(19) United States
(12) Patent Application Publication
(10) Pub. No.: US 2025/0026119 A1
(43) Pub. Date: Jan. 23, 2025

(54) LAMINATING DEVICE AND LAMINATION METHOD

(71) Applicant: THE JAPAN STEEL WORKS, LTD., Shinagawa-ku, Tokyo (JP)

(72) Inventor: Takayuki YAMAMOTO, Shinagawa-ku, Tokyo (JP)

(21) Appl. No.: 18/713,692

(22) PCT Filed: Dec. 15, 2022
(86) PCT No.: PCT/JP2022/046260

§ 371 Date: May 27, 2024

(30) Foreign Application Priority Data
Dec. 24, 2021 (JP) 2021-211344

(51) Int. Cl. B32B 37/10; B32B 37/00

(52) U.S. Cl. CPC B32B 37/10; B32B 37/0046

(57) ABSTRACT

A laminating device (3) configured to pressurize a laminate including a substrate layer and a resin layer between opposing boards at a predetermined temperature, in which at least one of the boards includes an elastic sheet (211, 328) that forms a pressurizing surface (328c), and a peripheral part (211b, 328b) of the elastic sheet (211, 328) has a hardness lower than that in a central part (211a, 328a) of the elastic sheet (211, 328). Accordingly, it is possible to provide a laminating device and a lamination method capable of preventing resin in the vicinity of an end of the laminate including the substrate layer and the resin layer from flowing out from a side surface of the laminate when the laminate is pressurized in the laminating device.

### TECHNICAL FIELD

The present invention relates to a laminating device and a lamination method for pressurizing a laminate including a substrate layer and a resin layer between opposing boards of a press device at a predetermined temperature.

### BACKGROUND ART

In each of Patent Literature 1 and 2, a laminate molding device which pressurizes a laminate including a substrate layer and a resin layer between opposing boards at a predetermined temperature is disclosed. The laminate molding device disclosed in Patent Literature 1 includes an upper pressure plate and a lower pressure plate, the lower pressure plate being raised to be pressed onto a substrate to form a laminate. The upper pressure plate, which has a semi-cylindrical shape or a hemispherical shape in which a central part of the upper pressure plate is thicker than a peripheral part thereof, is attached to a lower surface of a support member made of an elastic material in such a manner that the convex part of the upper pressure plate faces downward. The lower pressure plate is a planar one which is made of a material harder than that of the upper pressure plate and can be raised and lowered.

Further, the laminating device disclosed in Patent Literature 2 includes a vacuum press device in which a pair of heat boards with heating means that are opposed to each other are provided and at least one of these heat boards can be advanced toward or retracted from the other one of the heat boards. In this laminating device, by using the above vacuum press device, a film-shaped resin material is laminated on an uneven surface of a base material which has unevenness on at least one of front and back surfaces thereof, thereby forming a laminate. In this laminating device, an elastic press plate that pressurizes the film-shaped resin material is provided on the surface of one of the heat boards opposed to the film-shaped resin material that is closer to the film-shaped resin material.

### CITATION LIST

### Patent Literature

[Patent Literature 1] Japanese Unexamined Patent Application Publication No. H01-244467
[Patent Literature 2] Japanese Unexamined Patent Application Publication No. 2008-12918

### SUMMARY OF INVENTION

However, in Patent Literature 1 in which the pressure bonding between the thin film or the elastic material and the substrate extends from the central part of the substrate to the peripheral part of the substrate, resin in the central part tends to flow outside from the side surface of the laminate, although the above pressure bonding is effective in preventing air bubbles. On the other hand, in Patent Literature 2, it is unlikely that the aforementioned problem will occur. However, there is still a problem, as shown in [FIG. 7] accompanied by the present specification, that, when the laminate including the substrate layer and the resin layer is pressurized by the elastic sheet, stress concentrates in the vicinity of the end part of the laminate and the resin in the vicinity of the end part flows outside.

The present invention has been made to solve the aforementioned problem, and one of objects of the present invention is to provide a laminating device and a lamination method capable of preventing, when a laminate including a substrate layer and a resin layer is pressurized using an elastic sheet or an elastic film body, resin in the vicinity of an end of the laminate from flowing out from a side surface of the laminate. The other problems of the related art and the novel characteristics of the present invention will be made apparent from the descriptions of the specification and the accompanying drawings.

In a laminating device according to claim 1 of the present invention, at least one of boards includes an elastic sheet that forms a pressurizing surface, and a peripheral part of the elastic sheet has a hardness lower than that in a central part of the elastic sheet.

At least one of the boards includes an elastic sheet that forms a pressurizing surface, and a peripheral part of the elastic sheet has a hardness lower than that in a central part of the elastic sheet, whereby it is possible to prevent resin in the vicinity of an end of the laminate from flowing outside from a side surface of the laminate when laminate-molding is performed. A lamination method according to the present invention also have similar effects.

### BRIEF DESCRIPTION OF DRAWINGS

FIG. 1 is a schematic explanatory diagram of a laminating device according to a first embodiment;

FIG. 2 is an enlarged cross-sectional view of a main part of a vacuum laminating device of the laminating device according to the first embodiment when pressure is applied;

FIG. 3 is an enlarged cross-sectional view of a main part of a press device of the laminating device according to the first embodiment when the pressure is applied;

FIG. 4 is a plan view showing a relation between an elastic sheet of the press device of the laminating device and a laminate according to the first embodiment;

FIG. 5A is a side view illustrating the elastic sheet used for the laminating device;

FIG. 5B is a side view illustrating the elastic sheet used for the laminating device;

FIG. 5C is a side view illustrating the elastic sheet used for the laminating device;

FIG. 5D is a side view illustrating the elastic sheet used for the laminating device;

FIG. 5E is a side view illustrating the elastic sheet used for the laminating device;

FIG. 5F is a side view illustrating the elastic sheet used for the laminating device;

FIG. 6 is a plan view illustrating a plurality of elastic sheets used for the laminating device; and

FIG. 7 is an explanatory diagram showing a problem according to related art.

### DESCRIPTION OF EMBODIMENTS

### <Description of Configuration of Laminate Molding System and Laminating Device>

A laminate molding system 1 according to a first embodiment of the present invention will be described with reference to FIG. 1 in which a vacuum laminating device 2 and a press device 3 are shown in a cross-sectional view. In the laminate molding system 1, the press device 3 is disposed in a post-process of the vacuum laminating device 2. In the laminate molding system 1, an intermediate laminate A4 which has been conveyed from the vacuum laminating device 2 by carrier films F1 and F2 sent by a conveyance apparatus and which includes a substrate A1, which is a substrate layer having an uneven part, and a resin film A2, which is a resin layer, laminated to each other is pressure-molded by the press device 3.

A carrier film unwinding device 4 of a conveyance apparatus 10 serving as both a transfer device for transferring the substrate A1, which is the substrate layer, and the resin film A2, which is the resin device, and a tension device includes a lower unwinding roll 411 and a driven roll 412. The orientation of the lower carrier film F1 unwound from the unwinding roll 411 is changed to a horizontal state in the driven roll 412. A placement stage 413 for placing the substrate A1, which is the substrate layer, and the resin film A2, which is the resin layer, both of the substrate A1 and the resin film A2 being sent in an overlapping manner from the pre-process, is provided at a part where the lower carrier film F1 is changed to the horizontal state. Further, the carrier film unwinding device 4 forming the conveyance apparatus 10 includes an upper unwinding roll 414 and a driven roll 415, and the upper carrier film F2 unwound from the unwinding roll 414 is overlaid on a laminate A3 formed of the substrate A1 and the resin film A2 in the driven roll 415. The substrate A1 and the resin film A2 are transferred by being sandwiched between the carrier films F1 and F2. Then, when laminate molding is performed in the vacuum laminating device 2, which is the laminating device, or the press device 3 through the carrier films F1 and F2, the laminated film A2 is prevented from melting and adhering to a device part. In the press device 3, in particular, the use of the carrier films F1 and F2 also has an advantage in that a certain buffer action is imparted when the intermediate laminate A4 is pressurized. Further, depending on the type of a laminate molded article A5, the laminate molded article A5 is peeled off from the carrier films F1 and F2 after the temperature of the laminate molded article A5 removed from the press device 3 is lowered, whereby the peeling or releasing can be performed in a good condition.

The vacuum laminating device 2 disposed in the post-process of the carrier film unwinding device 4 forming the conveyance apparatus 10 pressurizes the laminate A3 formed of the substrate A1 and the resin film A2 by a pressurizing body such as a diaphragm 211, which is an elastic film body, in a chamber C in a vacuum state (pressure reduced state) and laminate-molds the intermediate laminate A4, which is a primary molded article. The vacuum laminating device 2 is provided in such a way that a lower board 213 can be raised and lowered with respect to a fixedly-provided upper board 212 by a rising/lowering mechanism 214, and the chamber C can be formed inside when the lower board 213 is raised and comes into contact with the upper board 212. The chamber C is connected to a vacuum pump that is not shown and is pressure reduceable. Further, a heat plate 215 is attached to the lower surface at the center of the upper board 212, and a heat-resistant elastic sheet 216 such as a rubber film (not shown) is attached to the surface of the heat plate 215 in such a way that it is bonded to a metal plate 218 or is directly attached thereto.

On the other hand, another heat plate 217 is attached to the upper surface at the center of the lower board 213. Further, the diaphragm 211, which is the elastic sheet formed of a heat-resistant rubber film such as a silicone rubber or a fluororubber, is attached to a part of the lower board 213 in the vicinity of the heat plate 217 in such a way that the diaphragm 211 covers the upper surface of the heat plate 217. Then, a pressurizing air is sent to a rear surface side of the diaphragm 211 by a compressor (not shown), whereby the diaphragm 211 expands in the chamber C and pressurizes the substrate A1 and the resin film A2 between the diaphragm 211 and the heat plate 217. Note that the diaphragm 211, which is an elastic sheet of the vacuum laminating device 2, may be attached to the upper board.

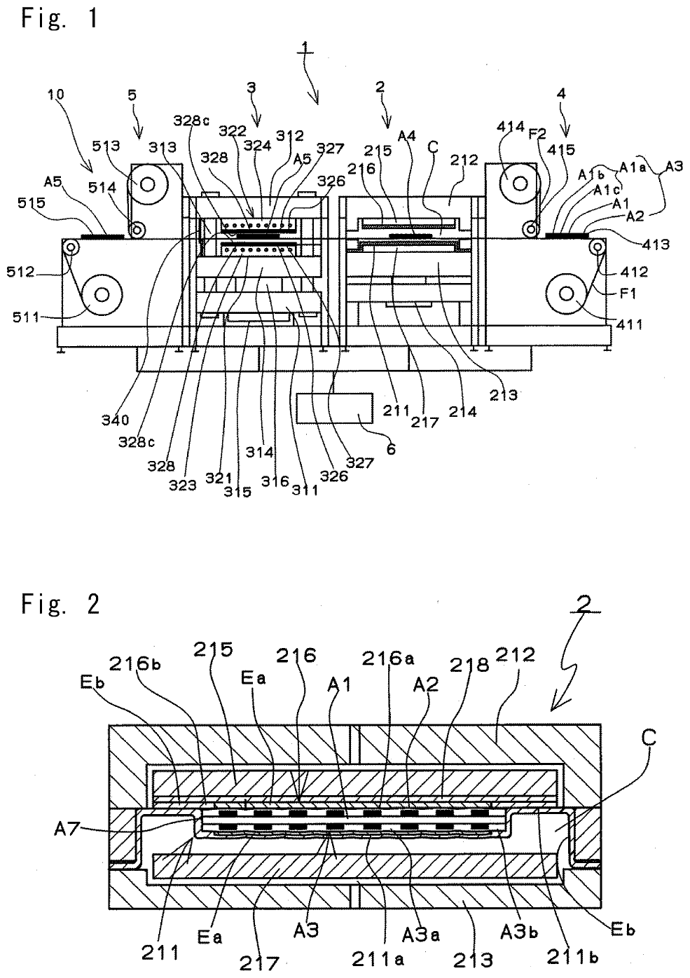

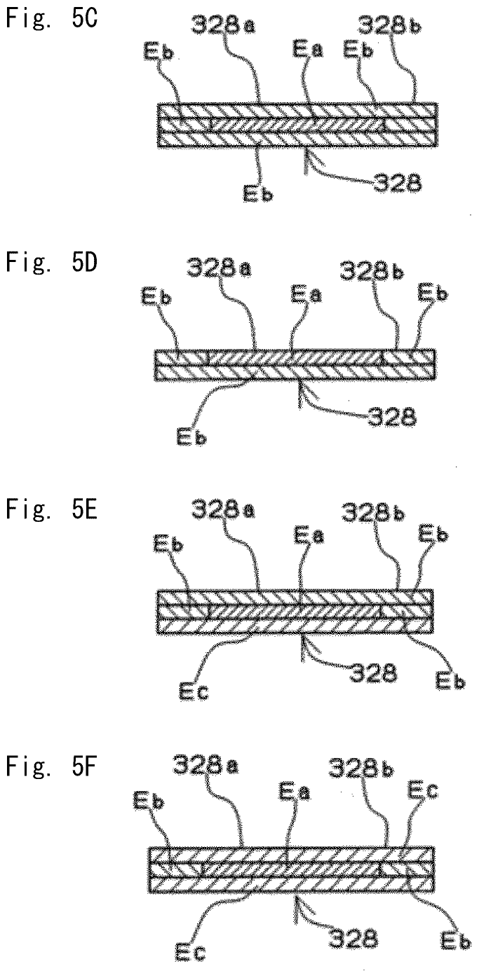

As shown in FIG. 2, in the diaphragm 211, which is an elastic sheet forming a part of the pressurizing means of the vacuum laminating device 2 according to this embodiment, the hardness of a peripheral part 211b is less than the hardness of a central part 211a. In this example, as shown in FIG. 5B, a concave part is provided in the central part of a rubber material Ea that corresponds to the whole area of the diaphragm 211, and a rubber material Eb having a high hardness is bonded to the concave part. This configuration is intended to achieve an object of making an elastic action of a part of the diaphragm 211, which is the elastic sheet, that is opposed to at least an outer peripheral part A3b of the laminate A3 smaller than an elastic modulus of a part of the diaphragm 211 that is opposed to a central part A3a of the laminate A3. In the diaphragm 211, which is the elastic sheet, to achieve the aforementioned configuration, the rubber material Ea or Eb used in the peripheral part 211b may be different from the rubber material Ea or Eb used in the central part 211a. Even though the central part 211a and the peripheral part 211b are made of the same material, the formulation ratio or bubble ratio may be made different from each other so that these elastic bodies may be different from each other only in hardness and elastic modulus thereof.

Regarding the aforementioned elastic sheet 216 on the side of the upper board, like the diaphragm 211, which is the elastic sheet, the hardness of the peripheral part 216b is less than the hardness of the central part 216a. In this example, the rubber material Eb having a small hardness (having a small elastic modulus) is used for the peripheral part 216b of the elastic sheet 216 and the rubber material Ea having a relatively large hardness (having a relatively small elastic modulus) is used for the central part 216a of the elastic sheet 216. Note that one of the whole surface of the diaphragm 211 or the whole surface of the elastic sheet 216 may be made of the same rubber material.

The press device 3 disposed in the series direction in the post-process of the vacuum laminating device 2 further pressurizes the intermediate laminate A4 which has been pressure-molded by the vacuum laminating device 2, the intermediate laminate A4 including the substrate A1, which is the substrate layer having an uneven part, and the resin film A2, which is the resin layer, and being in a state in which there is an uneven part on the side of the resin film A2, thereby performing pressure-molding to obtain an even flatter laminate molded article A5. The press device 3 includes a substantially rectangular base board 311 provided on the lower side, and tie bars 313 provided upright between vicinities of four corners of an upper board 312, which is a substantially rectangular fixed board located above the base board 31. In the press device 3, a lower board 314 which is a substantially rectangular movable board can be raised and lowered between the base board 311 and the upper board 312. A position sensor 340 for detecting the distance between these boards is attached between the upper board 312 and the lower board 314. Further, the position sensor 340 may be attached between a pressurizing member 322 on the side of the upper board and a pressurizing member 321 on the side of the lower board and detect the distance between the pressurizing member 321 and the pressurizing member 322. Note that the position sensor 340 is not essential in the present invention.

Further, one pressurizing cylinder 315, which is pressurizing means that is actuated by hydraulic pressure, is provided in the base board 311, and a ram 316 of the pressurizing cylinder 315 is fixed to the back surface of the lower board 314. The pressurizing cylinder may either be a single acting cylinder or a double acting cylinder. A pipeline that supplies hydraulic oil from a pump (not shown) is connected to a pressurized oil chamber (not shown) of the pressurizing cylinder 315, and a hydraulic sensor for measuring the hydraulic pressure of the hydraulic oil is provided in the pipeline. While the pump is not limited thereto, a pump that can control the number of rotations by a servomotor is used. Further, a servovalve for controlling the flow rate may be provided in the pipeline. The number of pressurizing means may be two or larger. Regardless of whether there is one pressurizing means or two or more pressurizing means, the pressurizing means does not impart different pressurizing forces to respective parts of a pressurizing surface 328c via the lower board 314 in terms of control.

Note that the pressurizing means of the press device 3 according to the first embodiment may be other systems including means for directly moving the lower board or the like by rotating a ball screw by using an electric motor such as a servomotor or means for moving the lower board or the like via a toggle device by using an electric motor such as a servomotor. Further, the press device 3 may be the one in which the upper board is lowered with respect to the lower board. Furthermore, while the press device 3 according to the first embodiment does not include a chamber capable of being in a vacuum state, it may include a chamber capable of being in a vacuum state and pressurization may be performed in the vacuum chamber.

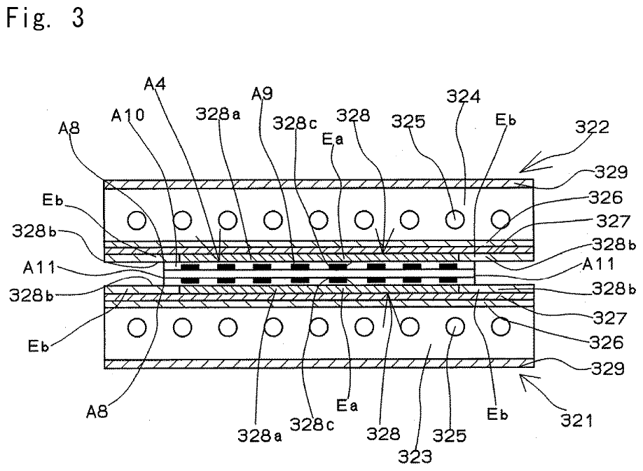

Since structures of the upper and lower pressurizing members 321 and 322 are substantially the same, the pressurizing member 321 of the lower board 314 will be described with reference to FIG. 3. The pressurizing member 321 includes a heat insulating material 329 that is provided between the lower board 314 and the pressurizing block body 323. Therefore, the pressurizing block body 323 of the press device 3 is attached to the lower board 314 via the heat insulating material 329 by using a bolt or the like that is not shown. The pressurizing block body 323, which is a block body having a predetermined thickness, includes a cartridge heater 325, which is heating means, inside thereof. Note that the heating means of the pressurizing member 321 may include, besides the cartridge heater 325, a rubber heater or the like that is provided on the surface or the like of the pressurizing block body 323.

On the surface of the pressurizing block body 323, a buffer 326 having a surface area the same as that of the pressurizing block body 323 is provided. The buffer 326 is made of a heat-resistant rubber, a resin film, paper, fiber, composites thereof, or a laminate material. The thickness of the buffer 326 is, for example, but not limited to, from 0.05 mm to 5.0 mm. Further, a hardness of the peripheral part of the buffer 326 may be greater than that of the central part of the buffer 326.

On the surface of the buffer 326, a metal plate 327 made of a hard material to which an elastic sheet 328 having a surface area the same as that of the buffer 326 is bonded is provided. In this embodiment, the plate formed of a hard material is made of stainless steel, other metal such as iron or aluminum, resin, ceramics, or wood may instead be used without any limitation. The thickness of the metal plate 327, is, for example, but not limited to, from 0.3 mm to 5.0 mm.

### <Description of Elastic Sheet of Press Device>

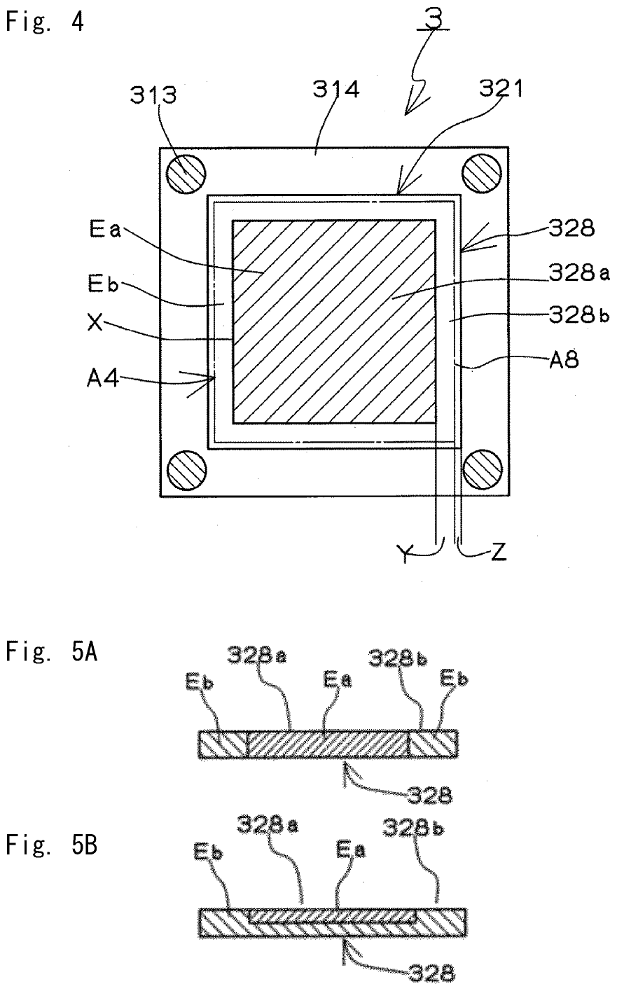

Next, the elastic sheet 328 that is bonded to the metal plate 327 and forms the pressurizing surface 328c will be described. As shown in FIGS. 3 and 4, a hardness of the peripheral part 328b of the elastic sheet 328 is less than that of the central part 328a of the elastic sheet 328. Then, an elastic modulus of a part of the elastic sheet 328 that is opposed to at least the outer peripheral part A4b of the intermediate laminate A4 is less than an elastic modulus of a part of the elastic sheet 328 that is opposed to the central part A4a of the intermediate laminate A4. In the elastic sheet 328 to achieve the aforementioned configuration, the material used in the peripheral part of the elastic sheet 328 may be different from the material used in the central part of the elastic sheet 328. Even though the peripheral part and the central part are made of the same material, the formulation ratio or bubble ratio may be made different from each other so that the elastic sheet 328 may include parts different from each other only in hardness thereof. In the present invention, the elastic sheet 328 may be directly attached to the pressurizing block body with no metal plate, or the elastic sheet 328 may be attached to the surface of the buffer 326 attached to the pressurizing block body 323. Alternatively, the metal plate 327 attached to the elastic sheet 328 may be directly attached to the pressurizing block body 323 without the buffer 326.

Further, as shown in FIG. 4, a boundary X between the rubber material Eb of the elastic sheet 328 having a low hardness and the rubber material Ea of the elastic sheet 328 having a high hardness is preferably provided in 30 mm in the inner direction Y relative to the outer peripheral end A8 and 10 mm in the outer direction Z relative to the outer peripheral end A8 in the position where the intermediate laminate A4 is molded. Therefore, the boundary may be formed on the pressurizing surface 328c of the intermediate laminate A4 or may be formed in a part other than the pressurizing surface 328c. The above boundary X varies depending on the type and the size of the laminate including the intermediate laminate A4.

The material of the elastic sheet 328 is a heat-resistant elastomer (rubber), and may contain other materials such as fiber. The material of the elastic sheet 328 is preferably silicone rubber or fluororubber, as an example. Regarding the heat resistance of the elastic sheet 328, the heat resistant temperature of the elastic sheet 328 is preferably at least 150° C., further preferably at least 180° C., and particularly preferably at least 230° C. As described above, the peripheral part 328b and the central part 328a of the elastic sheet 328 may be made of two or more kinds of heat-resistant elastomer (rubber) with different hardnesses even though they are made of the same material.

Regarding the hardness of the elastic sheet 328, the hardness of the peripheral part 328b is, for example, but not limited to, the Shore A hardness of 10° to 85°, and particularly preferably 15° to 40°. Further, the hardness of the central part 328a of the elastic sheet 328 is, for example, but not limited to, the Shore A hardness of 15° to 90°, and particularly preferably 20° to 60°. In any case, it is preferable that the hardness of the central part 328a of the elastic sheet 328 be made relatively high and the hardness of the peripheral part 328b of the elastic sheet 328 be made low.

The thickness of the elastic sheet 328 is, for example, but not limited to, from 0.2 mm to 6.0 mm, and particularly preferably from 0.5 mm to 3.0 mm. While the thickness of the peripheral part 328b is the same as that of the central part 328a in this embodiment, the thickness of the peripheral part 328b may be smaller than the thickness of the central part 328a by, for example, 0.01 mm to 1.0 mm. However, when the hardness of the peripheral part 328b of the elastic sheet 328 is different from the hardness of the central part 328a by at least a certain amount, it may be possible to make the thickness of the peripheral part 328b larger than the thickness of the central part 328a. In any case, it is preferable that a physical property for transmitting a pressing force to a part of the elastic sheet 328 that is opposed to at least the outer peripheral end A8 of the laminate such as the intermediate laminate A4 when the pressure is applied be less than a physical property for transmitting a pressing force to a part of the elastic sheet 328 that is opposed to the central part A9 of the laminate, a proportion of the pressing force transmitted to the outer peripheral end A8 be small, and a molten resin be prevented from flowing out (leaking out) from the side surface A11 of the intermediate laminate A4 or the like when the pressure is applied.

In this example, the pressurizing surface 328c of the elastic sheet 328 has a fine cloth grain shape. Instead, in order to ensure good mold release, the pressurizing surface 328c may be embossed with irregularities or may have a satin-like surface roughness, not a fine cloth grain shape. Furthermore, the pressurizing surface 328c of the elastic sheet 328 may have a completely flat shape.

In this embodiment, in the elastic sheet 328, each of the rubber material Eb having a low hardness that forms the peripheral part 328b and the rubber material Ea having a high hardness that forms the central part 328a provided inside the peripheral part 328b are bonded to the metal plate 327. The elastic sheet 328 may be bonded to the metal plate 327 or the pressurizing block body 323 by baking or by adhesive. The elastic sheet 328 may instead be bonded to the metal plate 327 or the pressurizing block body 323 by bolting or vacuum suction. In FIG. 3, the length of each of the pressurizing block body 323 forming the pressurizing member 321, the buffer 326, the metal plate 327, the elastic sheet 328 and the like in the thickness direction with respect to the length thereof in the horizontal direction is drawn much larger than it actually is.

Note that, in the present invention, it is sufficient that the hardness (or the elastic modulus) of the peripheral part 328b of the elastic sheet 328 of at least one device of the elastic sheet which is the diaphragm 211 of the vacuum laminating device 2 or the elastic sheet 328 which is the elastic pressurizing thin plate of the press device 3 be less than the hardness (or the elastic modulus) of the central part 328a of the elastic sheet 328. That is, the elastic sheet 328 of the vacuum laminating device 2 may have an even hardness (elastic modulus), and the hardness (elastic modulus) of the peripheral part 328b of the elastic sheet 328 of the press device 3 may be less than the hardness (elastic modulus) of the central part 328a thereof. Alternatively, the elastic sheet 328 of the press device 3 may have an even hardness (elastic modulus), and the hardness (elastic modulus) of the peripheral part 328b of the elastic sheet 328 of the vacuum laminating device 2 may be less than the hardness (elastic modulus) of the central part 328a thereof.

### <Further Description of Configuration of Laminate Molding System>

In the press device 3 according to the first embodiment, the upper board 312 has a pressurizing member 322 having the same side size, the same area, and the same structure as that of the lower board 314. That is, the upper board 312 also includes a pressurizing block body 324, a buffer 326, a metal plate 327, an elastic sheet 328 and the like having a configuration similar to that in FIG. 3.

Note that, in the present invention, the elastic sheet 328 that forms the pressurizing surface 328c may be included in at least one of the lower board 314 or the upper board 312, and the hardness of the peripheral part 328b may be lower than the hardness of the central part 328a in the elastic sheet 328. When, for example, the resin film A2 is laminated only on one surface of the substrate A1, the object may be achieved if the elastic sheet 328 of only the board that is opposed to the resin film A2 is formed in such a way that the hardness of the peripheral part 328b is less than the hardness of the central part 328a.

In the post-process of the press device 3, a carrier film winding device 5 forming the conveyance apparatus 10 that serves as both a transfer device and a tension device of the laminate molded article A5 is provided. The carrier film winding device 5 includes a lower winding roll 511 and a driven roll 512, and a lower carrier film F1 is wound by the winding roll 511. Further, the carrier film winding device 5 includes an upper winding roll 513 and a driven roll 514, an upper carrier film F2 is peeled off from the laminate molded article A5 at the part of the driven roll 514, and the upper carrier film F2 is wound around the upper winding roll 513. A take-out stage 515 of the laminate molded article A5 is provided at a part where only the lower carrier film F1 is fed in the horizontal state.

The control of the amount of feeding of each of the upper and lower carrier films F1 and F2 may be performed by detecting diameters of the films wound by the winding rolls 511 and 513 by measurement and controlling the numbers of rotations (rotation angles) of the winding rolls 511 and 513 by a servomotor. Further, a rotation number detection device such as a rotary encoder may be provided in the driven roll 512. Further, as the transfer device of the carrier films F1 and F2, a transfer device that grips both sides of the carrier films F1 and F2 and pulls the carrier films F1 and F2 for the post-process may be provided.

Next, a control device 6 of the laminate molding system 1 will be described. The control device 6 is connected to the vacuum laminating device 2, the press device 3, the carrier film unwinding device 4, and the carrier film winding device 5. In relation to the press device 3, in particular, the control device 6 controls the temperature of the heating means and the pressurizing force.

### <Description of Lamination Method>

Next, a lamination method of the substrate A1, which is the substrate layer, and the resin film A2, which is the resin layer, using the laminate molding system 1 according to the first embodiment will be described. In the laminate molding system 1 at the time of continuous molding, pressure-molding is concurrently performed in a batch-processing manner by sequence control in the press device 3, which is a laminating device just like the diaphragm-type vacuum laminating device 2. However, here, the description will be given along a molding order of a to-be-laminated material for one molding cycle, namely the substrate A1 and the resin film A2 (laminated film).

The substrate A1 placed on the placement stage 413 of the conveyance apparatus 10 is a circuit board for build-up having an uneven part Ala including a convex part A1b having a copper foil adhered to a substrate surface and a concave part A1c not having a copper foil. The thickness of the copper foil (height with respect to the substrate part) is, for example, but not limited thereto, about several μm to several tens μm, and is 0.1 mm or less in most cases. The resin film A2 is overlapped on each of upper and lower surfaces of the substrate A1 to form a laminate A3 for build-up molding. While only one laminate A3 is shown in FIG. 1, a plurality of laminates A3 may be laminate-molded at the same time.

The resin film A2 according to the first embodiment is an insulating film, which is used after PET films laminated on both respective surfaces thereof are peeled off from the original storage state. The main component of the resin material of the resin film A2 is a thermosetting resin or a thermosetting resin such as epoxy. Further, as materials other than the thermosetting resin, a thermoplastic resin, or various materials and additives are contained for the purpose of adjusting roughness, imparting flame retardancy, imparting low expansion, imparting fluidity, imparting film formability, low dielectric loss tangent (imparting insulating property), and lowering a water content. The film to be laminated may be, besides the insulating film, a photosensitive film or the like. The component of the film to be laminated may be, but not limited to, only a thermoplastic resin or only a thermosetting resin.

Then, the laminate A3 placed on the placement stage 413 is moved together with the upper and lower carrier films F1 and F2 with the rotational driving of the winding rolls 511 and 513, and is fed into and positioned in the chamber C of the vacuum laminating device 2 which is in the open state. At this time, as shown in FIG. 3, it is required that the peripheral part 211b of the diaphragm 211 in the vacuum laminating device 2 having a low hardness is stopped in such a manner that it is opposed to the outer edge of the laminate A3 formed of the substrate A1 and the resin film A2 sandwiched between the carrier films F1 and F2. In order to achieve this positioning, it is required to accurately perform control of the amount of feeding of the intermediate laminate A4 by the upper and lower carrier films F1 and F2 and control for stopping the laminate A3 in the press position of the press device 3 by using a servomotor or the like. A monitoring device such as a camera that monitors whether the laminate A3 is stopped in the press position may be attached as needed.

Next, in the vacuum laminating device 2, the chamber C is closed to form the chamber C in a vacuum state by a vacuum pump (not shown). When the chamber C is in a vacuum state, a pressurizing air is sent to the rear surface side of the diaphragm 211 to make the diaphragm 211 to expand into the chamber C, thereby pressuring the laminate A3 formed of the substrate A1 and the resin film A2 between the diaphragm 211 and the elastic sheet 216 of the heat plate 215 on the side of the upper board 212.

At this time, since the hardness of the peripheral part 211b of the diaphragm 211 is low, mainly this peripheral part 211b of the diaphragm 211 is extended and expands. Then, the central part 211a first comes into contact with the substrate A1 and the like, and the peripheral part 211b then comes into contact with the substrate A1 and the like shortly after the central part 211a does. The pressurizing force (surface pressure) that is applied to the substrate A1 and the like by the diaphragm 211 is, as one example, 0.01 MPa to 2.5 MPa, and particularly preferably 0.3 MPa to 1.0 MPa. Then, the substrate A1 and the resin film A2 are bonded to each other in such a manner that the laminated film A2 is buried in the concave part A1c of the substrate A1, whereby the intermediate laminate A4, which is the primary molded article, is laminate-molded.

Further, as described above, as shown in FIG. 2, in the diaphragm 211, the hardness of the peripheral part 211b is less than the hardness of the central part 211a. Therefore, when the substrate A1 and the resin film A2 are pressurized and laminated to each other, the force applied to the end A6 of the substrate A1 and the resin film A2 and the vicinity of the end is slightly lower than the force applied in the central part 211a. Further, since the hardness of the peripheral part 211b of the diaphragm 211 is low and thus the peripheral part 211b of the diaphragm 211 has a high flexibility, the force applied by the diaphragm 211 which comes into contact with the side surface A7 of the end A6 of the substrate A1 and the resin film A2 from the side surface A7 becomes relatively large. Therefore, in the vacuum laminating device 2 according to this embodiment, it is possible to prevent a problem that the resin layer flows outside from the side surface A7 when the pressure is applied.

However, there is still unevenness on the surface of the resin film A2 of the intermediate laminate A4 laminate-molded by the vacuum laminating device 2 in accordance with the shape of the uneven part Ala of the substrate A1. Further, at this time, if the content of inorganic materials in the resin film A2 to be used is high, the fluidity of the molten or softened resin is low, whereby it is likely that more uneven parts will remain even more.

When the intermediate laminate A4 obtained by bonding the substrate A1 having the uneven part Ala and the resin film A2 is laminate-molded in the vacuum laminating device 2, the chamber C is opened. Then, by feeding the next carrier films F1 and F2 by the carrier film unwinding device 4 and the carrier film winding device 5 which correspond to the conveyance apparatus 10, the intermediate laminate A4 is conveyed between the upper board 312 and the lower board 314 of the press device 3 and is stopped at a predetermined pressurize position. At this time as well, accurate feeding control of the upper and lower carrier films F1 and F2 is performed by a servomotor or the like by the same pitch as that when the laminate A3 is delivered to the vacuum laminating device 2. Further, a monitoring device such as a camera that monitors whether the intermediate laminate A4 is stopped in the press position may be attached to the side of the press device 3.

After the intermediate laminate A4 is stopped at a predetermined position of the press device 3 to further smooth the intermediate laminate A4, the pressurizing cylinder 315 of the press device 3 is actuated and the pressurizing process is started. In the pressurizing process, the lower board 314 and the pressurizing block body 323 and the like of the pressurizing member 321 are raised, the elastic sheet 328 attached to the pressurizing block body 323 comes into contact with the intermediate laminate A4 through the lower carrier film F1, which further pushes the intermediate laminate A4 upward, and the upper surface of the intermediate laminate A4 comes into contact with the elastic sheet 328 on the side of the upper board via the upper carrier film F2, and thereafter the pressurization control is started.

In this embodiment, pressurization control of the press device 3 is performed by pressure control and a surface pressure of, as an example, 0.01 MPa to 2.5 MPa, and further preferably from 0.5 MPa to 1.5 MPa is applied to the intermediate laminate A4. However, the pressure control may be the one in which the pressure is changed in the middle of the process. Further, pressure control may be performed in the first half of the pressurizing process of the press device 3 and position control (or speed control) may be performed in the second half of the pressurizing process. This does not exclude a case in which position control (or speed control) is performed for the entire process from the start to the end.

When the pressurizing process is performed by the press device 3, in the case where the whole surface of the elastic sheet 328 is constant, like in related art, as shown in FIG. 7, there is a problem that, when the intermediate laminate A4 including the substrate layer and the resin layer is pressurized, stress concentrates in the outer peripheral end A8 of the intermediate laminate A4 and the resin in the vicinity of the end flows outside from the side surface A7 of the intermediate laminate A4. However, in the present invention, as shown in FIG. 3, the elastic sheet 328 is provided on the surface of the metal plate 327, which is a plate made of a hard material, and the hardness of the peripheral part 328b of the elastic sheet 328 is less than the hardness of the central part 328a of the elastic sheet 328 (the hardness of the central part 328a is higher than the hardness of the peripheral part 328b). Therefore, when the intermediate laminate A4 is pressurized, a part including the outer peripheral end A8 of the intermediate laminate A4 is pressed at the peripheral part 328b of the elastic sheet 328 where the elastic modulus is small, and the central part A9 of the intermediate laminate A4 is pressed at the central part 328a of the elastic sheet 328 where the elastic modulus is large. In other words, in the elastic sheet 328, a physical property for transmitting a pressing force of the peripheral part 328b to the intermediate laminate A4 is larger than a physical property for transmitting a pressing force of the central part 328a to the intermediate laminate A4.

As a result, a compression pressure of a part of the elastic sheet 328 that is opposed to the peripheral part A10 of the intermediate laminate A4 becomes smaller than a compression pressure of a part of the elastic sheet 328 that is opposed to the central part A9 of the intermediate laminate A4, and thus there is no problem that the metal plate is bent as shown in FIG. 7 and stress concentrates in a part in the vicinity of the end part of the intermediate laminate A4. That is, since the metal plate maintains a substantially flat state, it is possible to prevent resin in the vicinity of the outer peripheral end A8 of the intermediate laminate A4 from flowing out from the side surface A11 of the laminate.

When the predetermined press process time ends, the press device 3 is opened and the laminate molded article A5 is sent to the take-out stage by feeding of the upper carrier film and the lower carrier film.

Then, the laminate molded article A5 is taken out on the take-out stage.

### Description of Other Embodiments

Next, a laminating device of a laminate molding system 1 according to other embodiments will be described. The laminate molding device according to the present invention may be the one in which only a single vacuum laminating device 2 including a diaphragm 211 shown in FIG. 1 is provided. Further, the laminate molding device according to the present invention may be the one in which one or a plurality of press devices is disposed in a post-process of the press device 3 of the laminate molding system 1 according to the first embodiment. In this case, the press device that is provided in the post-process may include the elastic sheet 328 as described in the present invention on the pressurizing surface. Alternatively, the press device that is provided in the post-process may be the one in which a buffer is provided between a pressurizing block body and a metal plate-form member, which is a pressurizing surface.

Alternatively, the laminate molding system 1 may be the one in which the vacuum laminating device 2 including the diaphragm 211 shown in FIG. 1 is not disposed and the press device 3 serves as a pressurizing device in the first pressurizing process. In this case, the press device 3 includes a vacuum chamber and constitutes a vacuum laminating device. The vacuum laminating device formed of the press device 3 itself forms a line of the laminate molding system. Further, the laminate molding system 1 may include one or a plurality of press devices in the post-process of the press device 3 (regardless of whether it includes a vacuum chamber) of the present invention, and each of the press devices may be a press device which is the same as the press device 3 or a press device including a thin metal plate forming a pressurizing surface on the surface of the pressurizing block body via a buffer.

### <Description of Variations of Combinations and Shapes of Elastic Sheets>

Next, with reference to FIGS. 5A-5F, some variations in which the hardness of the peripheral part 328b of the elastic sheet 328 and the hardness of central part 328a of the elastic sheet 328 in the present invention are made different from each other will be described. As shown in FIG. 5A, the elastic sheet 328 may be made of two kinds of rubber materials Ea and Eb and the peripheral part 328b and the central part 328a, which are formed of the different respective rubber materials Ea and Eb, may be formed without overlapping each other. Further, as shown in FIG. 5B, the elastic sheet 328 may be formed of two kinds of rubber materials Ea and Eb, and the rubber material Ea having a relatively high hardness may be disposed in a concave part Ebl of the central part 328a of the rubber material Eb which is provided on the whole surface and has a relatively low hardness. Further, as shown in FIG. 5C, the elastic sheet 328 may be formed of two kinds of rubber materials Ea and Eb, and the rubber material Ea having a high hardness may be held in the central part 328a which is between the rubber materials Eb having a low hardness on both surfaces. In this case, in the peripheral part 328b between the rubber materials Eb having a low hardness on the both surfaces, a rubber material Eb having a low hardness and whose type is the same as that of the rubber material Eb on the both surfaces is disposed. Further, as shown in FIG. 5D, the rubber material Ea harder than the rubber material Eb which covers the whole surface of one surface side and has a low hardness may be disposed in the central part 328a, and the rubber material Eb which is the same as the rubber material Eb that covers the whole surface may be disposed in the peripheral part.

Further, the elastic sheet 328 may be made of an elastic body such as three or more types of rubber materials. As one example, as shown in FIG. 5E, a hardness of the rubber material Eb and a hardness of a rubber material Ec that are provided on both surface sides may be different from each other, the peripheral part 328b of the rubber material that is sandwiched therebetween may be made of the same rubber material Eb or Ec as that of the rubber material Eb or Ec, which is one of the above surfaces, and the central part may be made of a material that is different from the rubber materials Eb and Ec of both surfaces and has a hardness greater than those of the rubber materials Eb and Ec of the peripheral part. Further, as shown in FIG. 5F, the rubber materials on the both surface sides may be the same rubber material Ec, and each of the rubber material Eb of the peripheral part of the rubber material sandwiched therebetween and the rubber material Ea of the central part of the rubber material sandwiched therebetween may be different from the rubber material Ec of the both surfaces, and the rubber material Eb of the peripheral part may have a hardness lower than that of the rubber material Ea of the central part 328a.

In each of FIGS. 5A to 5F, the upper side of the elastic sheet 328 may be the pressurizing surface 328c which comes into contact with the laminate such as the intermediate laminate A4 (in each of FIGS. 5A to 5F, the lower side of the elastic sheet 328 comes into contact with the metal plate 327), or the upper side of the elastic sheet 328 may come into contact with the metal plate 327 and the lower side of the elastic sheet 328 may be the pressurizing surface 328c that comes into contact with the laminate in each of FIGS. 5A to 5F. By making the hardness of the whole surface of the elastic sheet 328 on the side of the pressurizing surface 328c uniform and changing the hardness of the opposite rear surface side which comes into contact with, for example, the metal plate 327 in such a way that the central part 328a of the elastic sheet 328 has a hardness greater than that of the peripheral part 328b of the elastic sheet 328, a shape change associated with a distinct difference between hardnesses may not appear on a surface of a laminate such as the intermediate laminate A4. Further, the rubber materials Ea, Eb, Ec and the like of the elastic sheet 328 are preferably bonded by a heat-resistant adhesive. Alternatively, the rubber materials Ea, Eb, Ec and the like of the elastic sheet 328 are preferably engaged by thermofusion or bolts.

Further, the elastic sheet 328 may be processed in such a way that a hardness thereof gradually increases from the peripheral part 328b of the elastic sheet 328 to the central part 328a thereof although the elastic sheet 328 is made of a single piece of material. Alternatively, the elastic sheet 328 may be the one in which the rubber material Ea of the central part 328a and the rubber material Eb of the peripheral part 328b are bonded to each other on a surface in an inclined direction, not a vertical direction relative to the pressurizing surface 328c. In this case, in the elastic sheet 328, the hardness of the elastic sheet 328 gradually increases from the peripheral part 328b of the elastic sheet 328 to the central part 328a thereof.

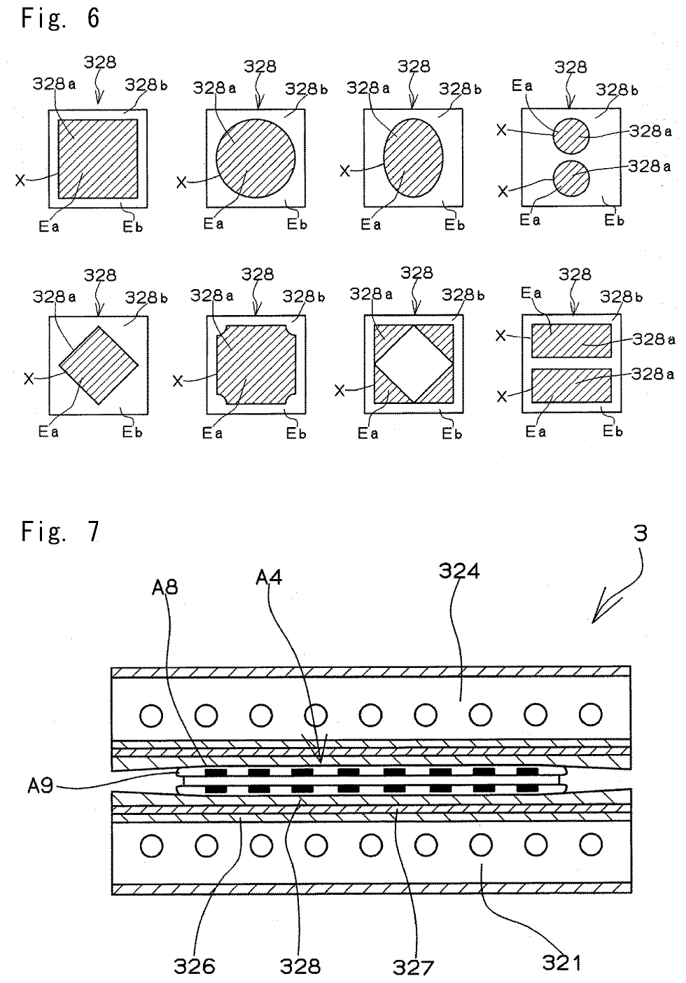

Further, an arrangement relation in which the peripheral part and the central part of the elastic sheet 328 are seen in a plan view may be changed as shown in FIG. 6 according to the shapes or the number of laminates. That is, the shape of the central part 328a of the elastic sheet 328 having a high hardness is not limited to rectangular (including a square and a rectangle) and may be circular, oval, diamond, or a shape with four chamfered corners. Further, in accordance with the number of laminates, a plurality of relatively high-hardness parts of the elastic sheet 328 may be provided. Therefore, “the elastic modulus in the part of the elastic sheet that is opposed to at least the outer peripheral part of the laminate is less than the elastic modulus in the part of the elastic sheet that is opposed to the central part of the laminate” in the present invention includes a structure in which two or more parts of the elastic sheet 328 having a hardness higher than that in the other part of the elastic sheet 328 (the two or more parts being parts of the elastic sheet 328 where the elastic modulus is large) are provided in the elastic sheet 328 in accordance with the number of laminates. While the central part 328a having a high hardness is hatched and the boundary X is shown by the solid line in FIG. 6, the whole pressurizing surface 328c on the front surface side may be one uniform elastic sheet and the hardness of the central part 328a on the central side or the rear surface side may be high.

The configuration of the elastic sheet 328 described above is intended to reduce the resin flow from the laminate using mainly the difference between physical properties such as the difference between the hardness of the peripheral part 328b and the hardness of the central part 328a. Instead, the resin flow from the laminate may be reduced by using a difference in thermal effects of the elastic sheet 328. Specifically, heat conductivity, which is one of heat transfer properties of at least a part of the elastic sheet 328 that is opposed to the outer peripheral end A8 of the laminate such as the intermediate laminate A4 is made smaller than the heat conductivity, which is one of heat transfer properties of a part of the laminate that is opposed to the central part A9. Accordingly, in the pressurizing surface 328c of the elastic sheet 328, the temperature of the central part 328a becomes high and the temperature of the peripheral part 328b becomes low. As a result, the resin flow in the vicinity of the outer peripheral end A8 of the intermediate laminate A4 that comes into contact with the pressurizing surface 328c of the elastic sheet 328 of the peripheral part is reduced. Note that the buffer material used in the peripheral part 328b of the elastic sheet 328 and the buffer material used in the central part 328a of the elastic sheet 328 may have the same heat conductivity, and the difference between heat transfer properties may be caused by the difference between porosities or the difference between other mixed substances.

Although the present invention is not listed one by one, the present invention is not limited to those of the first embodiment and it goes without saying that the present invention is also applied to those modified based on the gist of the present invention by those skilled in the art and those obtained by multiplying the respective descriptions. The laminated molded article A5 laminate-molded in the laminate molding system 1 may be, other than a build-up substrate, another circuit board, a semiconductor wafer, or the like without any limitation. Further, the substrate layer is not limited to the substrate.

This application is based upon and claims the benefit of priority from Japanese Patent Application No. 2021-211344, filed on Dec. 24, 2021, the disclosure of which is incorporated herein in its entirety by reference.

### REFERENCE SIGNS LIST

1 LAMINATE MOLDING SYSTEM
2 VACUUM LAMINATING DEVICE
3 PRESS DEVICE
212, 312 UPPER BOARD
213, 314 LOWER BOARD
321, 322 PRESSURIZING MEMBER
323, 324 PRESSURIZING BLOCK BODY
326 BUFFER
327 METAL PLATE
328 ELASTIC SHEET
328A CENTRAL PART
328B PERIPHERAL PART
328C PRESSURIZING SURFACE
Ea, Eb, Ec RUBBER MATERIAL

1. A laminating device configured to pressurize a laminate including a substrate layer and a resin layer between opposing boards at a predetermined temperature, wherein
at least one of the boards includes an elastic sheet that forms a pressurizing surface.

2. The laminating device according to claim 1, wherein
a physical property for transmitting a pressing force to a part of the elastic sheet that is opposed to at least an outer peripheral end of the laminate when the pressure is applied is smaller than a physical property for transmitting a pressing force to a part of the elastic sheet that is opposed to a central part of the laminate.

3. The laminating device according to claim 1, wherein
an elastic modulus of a part of the elastic sheet that is opposed to at least an outer peripheral part of the laminate is smaller than an elastic modulus of a part of the elastic sheet that is opposed to a central part of the laminate.

4. The laminating device according to claim 1, wherein
a heat transfer property of a part of the elastic sheet that is opposed to at least an outer peripheral part of the laminate is less than a heat transfer property of a part of the elastic sheet that is opposed to a central part of the laminate.

5. A lamination method for pressurizing a laminate including a substrate layer and a resin layer between opposing boards at a predetermined temperature, wherein
at least one of the boards includes an elastic sheet that forms a pressurizing surface, and
a part of the laminate that includes an outer peripheral end is pressed by a part of the elastic sheet having a small elastic modulus and a central part of the laminate is pressed by a part of the elastic sheet having a large elastic modulus.

6. The lamination method according to claim 5, wherein the laminate is a build-up substrate.

7. The laminating device according to claim 1, wherein a peripheral part of the elastic sheet has a hardness lower than that in a central part of the elastic sheet.
